(19) United States
(12) Patent Application Publication
(10) Pub. No.: US 2025/0287759 A1
(43) Pub. Date: Sep. 11, 2025

(54) DISPLAY DEVICE AND METHOD OF MANUFACTURING THE SAME

(71) Applicant: Japan Display Inc., Tokyo (JP)

(72) Inventors: Kenichi TAKEMASA, Tokyo (JP); Kazuyuki YAMADA, Tokyo (JP); Keisuke ASADA, Tokyo (JP); Daiki ISONO, Tokyo (JP)

(21) Appl. No.: 19/050,290

(22) Filed: Feb. 11, 2025

(30) Foreign Application Priority Data
Mar. 8, 2024 (JP) 2024-035681

(51) Int. Cl. H10H 29/855; H10H 29/854

(52) U.S. Cl. CPC H10H 29/8552; H10H 29/854

(57) ABSTRACT

A display device includes a plurality of LED elements mounted on a substrate, a first resin layer that seals the LED elements, a first light shielding layer arranged on the first resin layer, a second resin layer arranged on the first light shielding layer, and a second light shielding layer arranged on the second resin layer. The first light shielding layer includes a plurality of first light shielding portions and a plurality of first openings. The second light shielding layer includes a plurality of second light shielding portions and a plurality of second openings. Each of the first light shielding portions and the second light shielding portions includes a third opening. Each of the first light shielding portions is arranged at a position overlapping with any of the second openings. Each of the second light shielding portions is arranged at a position overlapping with any of the first openings.

### CROSS REFERENCES TO RELATED APPLICATIONS

The present application claims priority to Japanese Patent Application No. 2024-35681 filed on Mar. 8, 2024, the disclosure of which is incorporated herein by reference.

### TECHNICAL FIELD

The present invention relates to a display device.

### BACKGROUND

Patent Document 1 (Japanese Unexamined Patent Application Publication No. 2021-67763) discloses a micro LED display device in which LED elements are sealed by a sealing layer.

Patent Document 2 (Japanese Unexamined Patent Application Publication No. 2017-32812) discloses a display device in which light shielding portions formed in stripes intersect with each other.

### SUMMARY

There is a micro LED display device using a plurality of LED elements (inorganic light emitting diode elements) as light emitting elements. The inventors of this application have been studying a technique for improving the performance of a display device using a plurality of LED elements like the micro LED display device.

An object of the present invention is to provide a technique capable of improving the performance of a display device.

A display device according to one embodiment includes: a plurality of light emitting diode elements mounted on a first substrate, a first resin layer that seals the plurality of light emitting diode elements, a first light shielding layer arranged on the first resin layer, a second resin layer arranged on the first light shielding layer, and a second light shielding layer arranged on the second resin layer. Each of the first resin layer and the second resin layer is made of an organic material containing a photocurable resin component that is cured by light irradiation. The first light shielding layer includes a plurality of first light shielding portions and a plurality of first openings that are alternately arranged along each of a first direction and a second direction intersecting with the first direction. The second light shielding layer includes a plurality of second light shielding portions and a plurality of second openings that are alternately arranged along each of the first direction and the second direction. Each of the plurality of first light shielding portions and the plurality of second light shielding portions includes a third opening arranged at a position that overlaps with any of the plurality of light emitting diode elements. An opening area of the third opening is smaller than an opening area of the first opening and an opening area of the second opening. Each of the plurality of first light shielding portions is arranged at a position that overlaps with any of the plurality of second openings. Each of the plurality of second light shielding portions is arranged at a position that overlaps with any of the plurality of first openings.

### BRIEF DESCRIPTION OF DRAWINGS

FIG. 1 is a plan view illustrating a configuration example of a micro LED display device according to an embodiment;

FIG. 2 is a circuit diagram illustrating a configuration example of a circuit around a pixel illustrated in FIG. 1;

FIG. 3 is a transparent enlarged plan view illustrating an example of a peripheral structure of an LED element arranged in each of the plurality of pixels of the display device illustrated in FIG. 1;

FIG. 4 is an enlarged cross-sectional view taken along the line A-A in FIG. 3;

FIG. 5 is an enlarged cross-sectional view taken along the line B-B in FIG. 4;

FIG. 6 is an enlarged plan view illustrating a light shielding layer of two light shielding layers illustrated in FIG. 4 and FIG. 5, which is arranged at a position relatively closer to an LED element, and a substrate supporting it;

FIG. 7 is an enlarged plan view illustrating a light shielding layer of the two light shielding layers illustrated in FIG. 4 and FIG. 5, which is arranged at a position relatively farther from the LED element, and a substrate supporting it;

FIG. 8 is an enlarged cross-sectional view taken along the line C-C in FIG. 6 and FIG. 7;

FIG. 9 is an enlarged cross-sectional view illustrating a studied example for FIG. 8;

FIG. 10 is a transparent enlarged plan view illustrating a state where the substrate illustrated in FIG. 6 and the substrate illustrated in FIG. 7 are overlapped with each other;

FIG. 11 is an enlarged plan view illustrating a modification of the light shielding layer illustrated in FIG. 6;

FIG. 12 is an enlarged plan view illustrating a modification of the light shielding layer illustrated in FIG. 7;

FIG. 13 is an enlarged cross-sectional view taken along the line D-D in FIG. 11 and FIG. 12;

FIG. 14 is an enlarged plan view illustrating another modification of the light shielding layer illustrated in FIG. 6;

FIG. 15 is an enlarged plan view illustrating another modification of the light shielding layer illustrated in FIG. 7;

FIG. 16 is an enlarged plan view illustrating an example of a layout of a light shielding layer stacked on the substrate illustrated in FIG. 15; and

FIG. 17 is an enlarged cross-sectional view taken along the line E-E in FIG. 14, FIG. 15, and FIG. 16.

### DETAILED DESCRIPTION OF THE INVENTION

Hereinafter, each embodiment of the present invention will be described with reference to drawings. Note that the disclosure is merely an example, and it is a matter of course that any alteration that is easily made by a person skilled in the art while keeping a gist of the present invention is included in the range of the present invention. In addition, the drawings schematically illustrate a width, a thickness, a shape, and the like of each portion as compared with actual aspects in order to make the description clearer, but the drawings are merely examples and do not limit the interpretation of the present invention. Further, the same elements as those described in relation to the foregoing drawings are denoted by the same or related reference characters in this specification and the respective drawings, and detailed descriptions thereof will be omitted as appropriate.

### Display Device

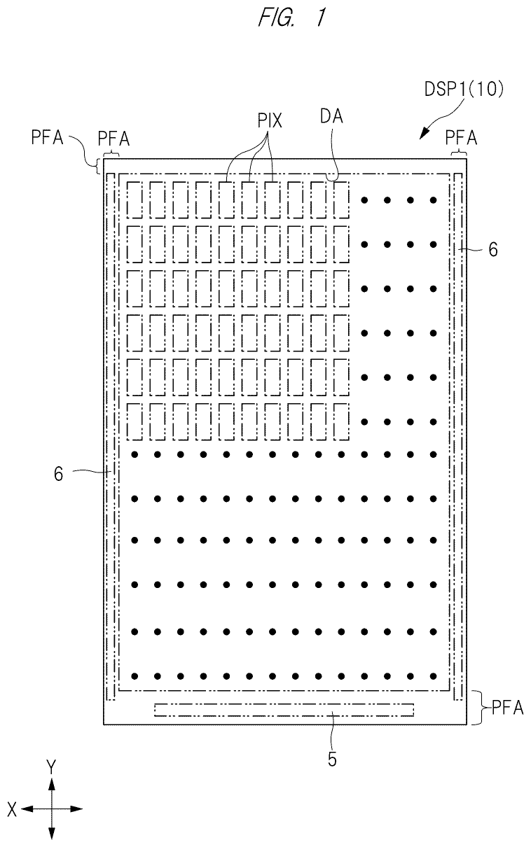

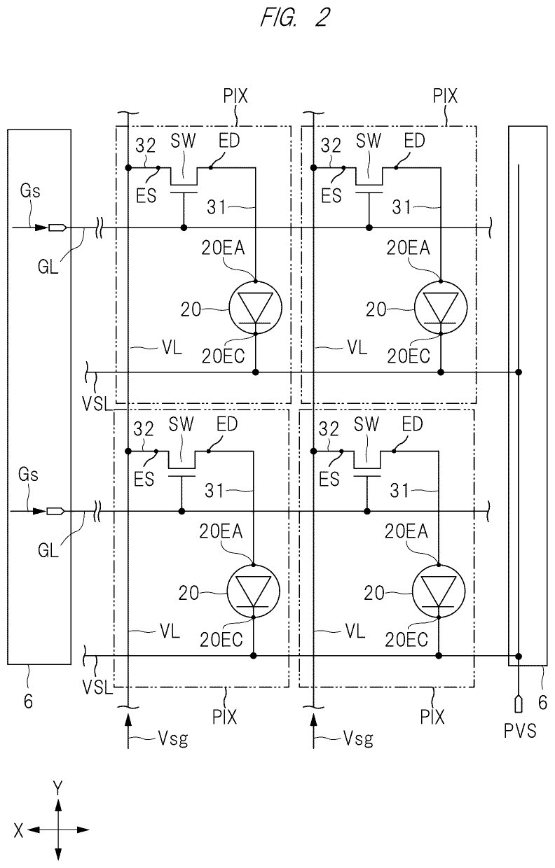

First, a configuration example of a micro LED display device, which is a display device of this embodiment, will be described. FIG. 1 is a plan view illustrating a configuration example of a micro LED display device according to an embodiment. In FIG. 1, the boundary between a display region DA and a peripheral region PFA, a control circuit 5, a drive circuit 6, and a plurality of pixels PIX are each indicated by two-dot dashed lines. FIG. 2 is a circuit diagram illustrating a configuration example of a circuit around the pixel illustrated in FIG. 1.

FIG. 1 illustrates the X direction and the Y direction. The X direction and the Y direction intersect with each other. In the example described below, the X direction is orthogonal to the Y direction. In the following, an X-Y plane including the X direction and the Y direction will be described as a plane parallel to a display surface of the display device. In the following description, “in plan view” means the case where a plane parallel to the X-Y plane is viewed, unless it is explicitly stated that it should be interpreted in different meaning. Furthermore, as will be described later, the normal direction with respect to the X-Y plane will be referred to as the “Z direction” or the thickness direction. The X direction, the Y direction, and the Z direction are directions that intersect with each other, and more specifically, are directions that are orthogonal to each other.

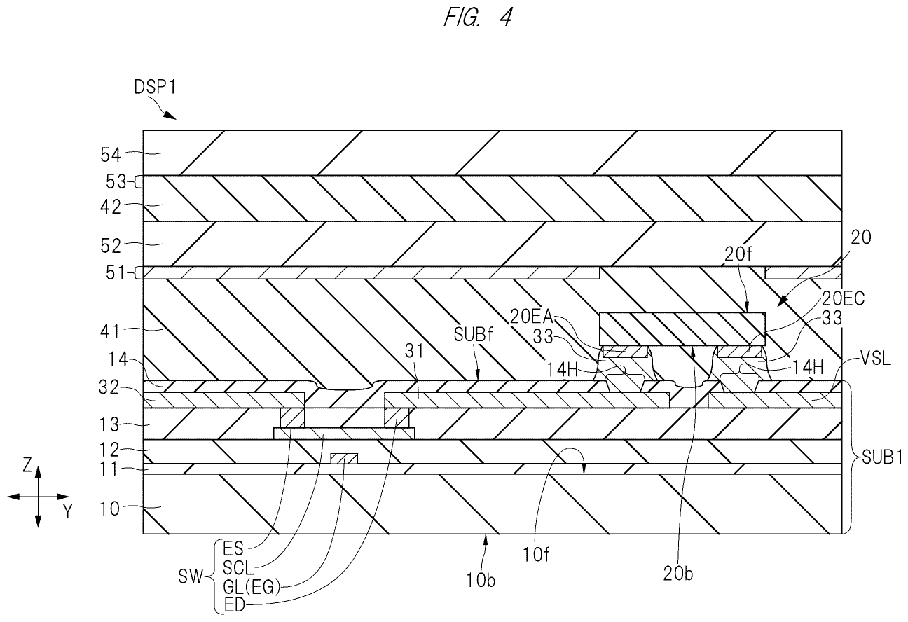

As illustrated in FIG. 1, a display device DSP1 of this embodiment includes the display region DA, the peripheral region PFA surrounding the display region DA in a frame shape, and the plurality of pixels PIX arranged in a matrix in the display region DA. Further, the display device DSP1 includes a substrate 10, the control circuit 5 formed on the substrate 10, and the drive circuit 6 formed on the substrate 10. The substrate 10 is made of glass or a resin. As illustrated in FIG. 4, the substrate 10 has a surface 10f and a surface 10b on a side opposite to the surface 10f.

The control circuit 5 is a control circuit configured to control the driving of a display function of the display device DSP1. For example, the control circuit 5 is a driver IC (Integrated Circuit) mounted on the substrate 10. In the example illustrated in FIG. 1, the control circuit 5 is arranged along one short side of the four sides of the substrate 10. Furthermore, in an example of this embodiment, the control circuit 5 includes a signal line drive circuit configured to drive a wiring (video signal wiring) VL (see FIG. 2) connected to the plurality of pixels PIX. However, the position and configuration example of the control circuit 5 are not limited to those in the example illustrated in FIG. 1, and there are various modifications. For example, in FIG. 1, a circuit board such as a flexible board may be connected to the position illustrated as the control circuit 5, and the above-described driver IC may be mounted on the circuit board. Further, for example, the signal line drive circuit configured to drive the wiring VL may be formed separately from the control circuit 5.

The drive circuit 6 includes a circuit configured to drive scan signal lines GL (see FIG. 2 described later) in the plurality of pixels PIX. Also, the drive circuit 6 includes a circuit configured to supply a reference potential to the LED element mounted in each of the plurality of pixels PIX. The drive circuit 6 drives the plurality of scan signal lines GL based on control signals from the control circuit 5. In the example illustrated in FIG. 1, the drive circuit 6 is arranged along each of two long sides of the four sides of the substrate 10. However, the position and configuration example of the drive circuit 6 are not limited to those in the example illustrated in FIG. 1, and there are various modifications. For example, in FIG. 1, a circuit board such as a flexible board may be connected to the position illustrated as the control circuit 5, and the above-described drive circuit 6 may be mounted on the circuit board.

Next, a circuit configuration example of the pixel PIX will be described with reference to FIG. 2. Note that FIG. 2 illustrates four pixels PIX representatively, but each of the plurality of pixels PIX illustrated in FIG. 1 includes the circuit similar to the pixel PIX illustrated in FIG. 2. In the following description, the circuit including a switch and an LED element 20 in the pixel PIX may be referred to as a pixel circuit. The pixel circuit is a voltage signal circuit configured to control the light emission state of the LED element 20 according to a video signal Vsg supplied from the control circuit 5 (see FIG. 1).

As illustrated in FIG. 2, the pixel PIX includes the LED element 20. The LED element 20 is a micro light emitting diode mentioned above. The LED element 20 has an anode electrode 20EA and a cathode electrode 20EC. The cathode electrode 20EC of the LED element 20 is connected to a wiring VSL to which a reference potential (fixed potential) PVS is supplied. The anode electrode 20EA of the LED element 20 is electrically connected to a drain electrode ED of a switching element SW via a wiring 31.

The pixel PIX includes the switching element SW. The switching element SW is a transistor configured to control a connection state (on state or off state) between the pixel circuit and the wiring VL in response to a control signal Gs. The switching element SW is, for example, a thin film transistor. When the switching element SW is in the on state, the video signal Vsg is input to the pixel circuit from the wiring VL.

The drive circuit 6 includes a shift register circuit, an output buffer circuit, and others (not illustrated). The drive circuit 6 outputs pulses based on a horizontal scanning start pulse transmitted from the control circuit 5 (see FIG. 1), and outputs the control signal Gs.

Each of the plurality of scan signal lines GL extends in the X direction. The scan signal line GL is connected to a gate electrode of the switching element SW. When the control signal Gs is supplied to the scan signal line GL, the switching element SW is turned on and the video signal Vsg is supplied to the LED element 20.

### Peripheral Structure of LED Element

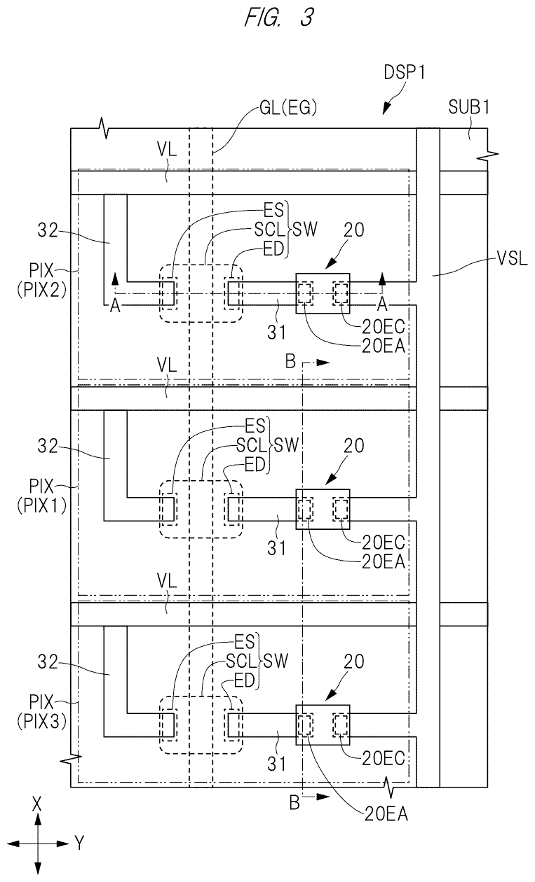

Next, the peripheral structure of the LED element arranged in each of the plurality of pixels PIX illustrated in FIG. 1 will be described. FIG. 3 is a transparent enlarged plan view illustrating an example of a peripheral structure of an LED element arranged in each of the plurality of pixels of the display device illustrated in FIG. 1. In FIG. 3, the illustration of each of an inorganic insulating layer 14, a resin layer 41, a light shielding layer 51, a substrate 52, a resin layer 42, a light shielding layer 53, and a substrate 54 illustrated in FIG. 4 and FIG. 5 is omitted. In FIG. 3, outlines of semiconductor layers, electrodes, and scan signal lines are indicated by dotted lines. FIG. 4 is an enlarged cross-sectional view taken along the line A-A in FIG. 3. FIG. 5 is an enlarged cross-sectional view taken along the line B-B in FIG. 4.

As illustrated in FIG. 3, the display device DSP1 has the plurality of pixels PIX including a pixel PIX1 (pixel PIX1, pixel PIX2, and pixel PIX3 in the example illustrated in FIG. 3). Each of the plurality of pixels PIX has the switching element SW, the LED element (light emitting diode element) 20, the wiring 31, and a wiring 32.

Note that, in each of the pixels PIX1, PIX2, and PIX3, for example, the LED element 20 configured to emit visible light of one color of red, green, and blue is mounted, and the switching element SW configured to drive the LED element 20 is formed. The color display is possible by controlling the output and timing of the visible light emitted from the LED elements 20 provided in the pixels PIX1, PIX2, and PIX3. When a plurality of pixels PIX configured to emit visible light of different colors are combined in this way, the pixel PIX for each color is sometimes referred to as a sub-pixel, and the set of the plurality of pixels PIX is sometimes referred to as a pixel. In this embodiment, the part corresponding to the sub-pixel mentioned above is referred to as the pixel PIX.

The wiring 31 is electrically connected to the drain electrode ED of the switching element SW and the anode electrode 20EA of the LED element 20. The wiring 32 is connected to a source electrode ES of the switching element SW. In the example illustrated in FIG. 3, the wiring 32 has a bent structure, and one end thereof is connected to the source electrode ES of the switching element SW and the other end thereof is connected to the wiring VL. The scan signal line GL is used as the gate electrode EG of the switching element SW.

The display device DSP1 further includes the wiring VL extending along the Y direction across the plurality of pixels PIX (see FIG. 2) and electrically connected to the wiring 32 and the wiring VSL extending along the X direction intersecting with the Y direction (orthogonally in FIG. 3) across the plurality of pixels PIX and electrically connected to the cathode electrode 20EC of the LED element 20. Note that the layout illustrated in FIG. 3 is an example, and there are various modifications. For example, as a modification for FIG. 3, the structure in which the switching element SW has a gate electrode (not illustrated) and the gate electrode is connected to the scan signal line GL is also possible. In this modification, the scan signal line GL may be arranged at a position that does not overlap with a semiconductor layer SCL.

As illustrated in FIG. 4, the display device DSP1 is an electronic device that includes the substrate 10 made of glass or a resin and a plurality of insulating layers stacked on the substrate 10. The plurality of insulating layers provided in the display device DSP1 include an inorganic insulating layer 11, an inorganic insulating layer 12, an inorganic insulating layer 13, and an inorganic insulating layer 14 stacked on the substrate 10. The substrate 10 has the surface 10f and the surface 10b on the side opposite to the surface 10f. Each of the inorganic insulating layers 11, 12, 13, and 14 is stacked on the surface 10f of the substrate 10.

The switching element SW includes the inorganic insulating layer 12 formed on the substrate 10, the semiconductor layer SCL formed on the inorganic insulating layer 12, the drain electrode ED connected to a drain region of the semiconductor layer SCL, the source electrode ES connected to a source region of the semiconductor layer SCL, and the inorganic insulating layer 13 covering the semiconductor layer SCL. Each of the wiring 31 and the wiring 32 is a stacked film of, for example, a conductor layer made of titanium or a titanium alloy and a conductor layer made of aluminum or an aluminum alloy. A stacked film in which an aluminum layer is sandwiched between titanium layers is referred to as a TAT stacked film.

The example illustrated in FIG. 4 is an example of the bottom gate type in which the gate electrode EG is located between the semiconductor layer SCL and the substrate 10. In the case of the bottom gate type, a part of the inorganic insulating layer 12 located between the gate electrode EG and the semiconductor layer SCL functions as a gate insulating layer. In addition, the inorganic insulating layer 12 also functions as a base layer for forming the semiconductor layer SCL. Note that the position of the gate electrode EG is not limited to that in the example illustrated in FIG. 4, and a top gate type described later as a modification is also possible.

The material constituting each of the inorganic insulating layers 11, 12, 13, and 14 is not particularly limited. For example, silicon oxide (SiO2) and silicon nitride (SiN) can be used. Further, the semiconductor layer SCL is a semiconductor film made of a silicon film doped with an impurity of P or N conductivity type.

Each of the source electrode ES and the drain electrode ED is a contact plug for making electrical contact with either the source region or the drain region of the semiconductor layer SCL. The material of the contact plug is, for example, tungsten. As a modification for FIG. 4, contact holes may be formed in the inorganic insulating layer 13 so as to expose the source region and the drain region of the semiconductor layer SCL, and a part of the wiring 31 and a part of the wiring 32 may be buried in the contact holes, respectively. In this case, the parts of the wiring 31 and the wiring 32 buried in the contact holes are in contact with the semiconductor layer SCL, and the contact interfaces between the wirings 31 and 32 and the semiconductor layer SCL can be regarded as the drain electrode ED and the source electrode ES.

A stacked body of the substrate 10 and the plurality of insulating layers (inorganic insulating layers 11, 12, 13, and 14 in the example illustrated in FIG. 4) stacked on the substrate 10 is defined as a substrate SUB1. The substrate SUB1 has a surface SUBf.

Furthermore, the display device DSP1 includes a plurality of bump electrodes 33. The bump electrode 33 is a terminal for mounting the LED element 20 on the substrate 10. Therefore, one of the two bump electrodes 33 is connected to the anode electrode 20EA of the LED element 20, and the other is connected to the cathode electrode 20EC of the LED element 20.

The bump electrode 33 is connected to the wiring 31 at a position that overlaps with an opening 14H formed in the inorganic insulating layer 14, and protrudes from the inorganic insulating layer 14. Further, the bump electrode 33 is made of, for example, solder containing tin. Alternatively, the bump electrode 33 may be a stacked body of a metal layer made of a metal material having a higher electrical conductivity than solder such as copper and a solder layer.

Also, in the case of this embodiment, the LED element 20 is sealed by the resin layer 41 as illustrated in FIG. 4 and FIG. 5. The display device DSP1 includes the resin layer 41 in which the LED element 20 is sealed, the light shielding layer 51 arranged on the resin layer 41, the resin layer 42 arranged on the light shielding layer 51, and the light shielding layer 53 arranged on the resin layer 42.

A light shielding member 50 is partially arranged in each of the light shielding layer 51 and the light shielding layer 53. The light shielding member 50 arranged in each of the light shielding layer 51 and the light shielding layer 53 is a black or dark-colored member having a property of absorbing visible light. Examples of the material constituting the light shielding member 50 include a resin mixed with a black pigment, metal such as chromium, or metal oxide such as chromium oxide.

The light shielding layer 51 and the light shielding layer 53 have a function of suppressing external light irradiated from outside of the display device DSP1 from reaching the substrate SUB1. In addition, the light shielding layer 51 and the light shielding layer 53 have a function of suppressing reflected light of external light reflected from a wiring pattern of the substrate SUB1 (for example, the wiring 31, the wiring 32, the wiring VL, or the wiring VSL illustrated in FIG. 3) from being visually recognized as mixed color with a displayed image. The wiring pattern of the substrate SUB1 is connected to at least one of the plurality of LED elements 20.

The micro LED display device using the LED elements 20, which are self-luminous elements, can achieve a higher contrast ratio as compared with, for example, a liquid crystal display device. However, the reflection of external light from the substrate SUB1 on which the LED elements 20 are mounted causes the decrease in the contrast ratio.

In the case where the light shielding layers 51 and 53 are arranged on the substrate SUB1 and the LED elements 20 are arranged between the light shielding layers 51 and 53 and the substrate SUB1 as in this embodiment, it is possible to suppress the intrusion of external light and the emission of reflected light as described above, resulting in the increase in contrast ratio of the display device DSP1.

The detailed structures of the light shielding layer 51 and the light shielding layer and 53 will be described later.

### Details of Light Shielding Layer

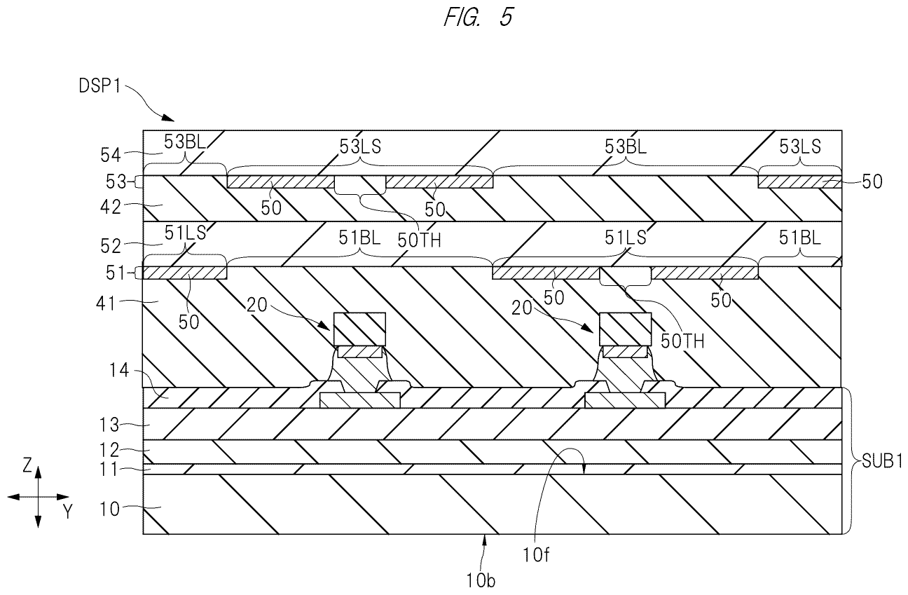

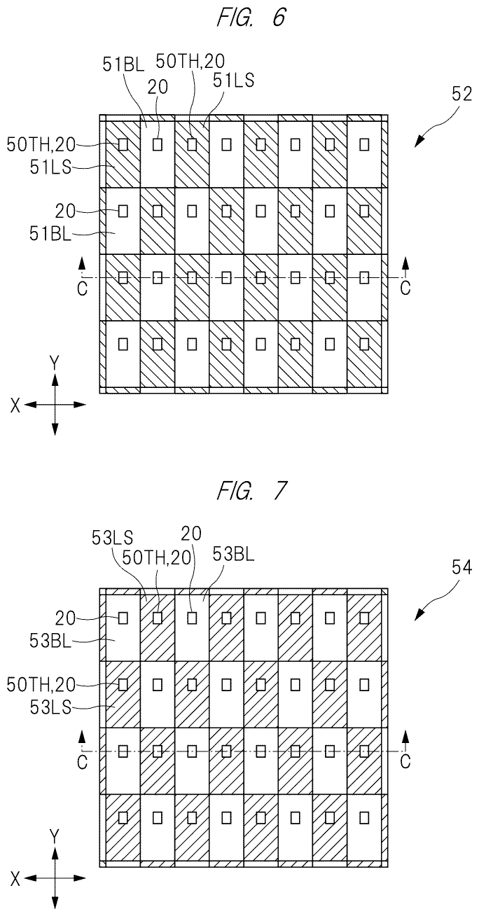

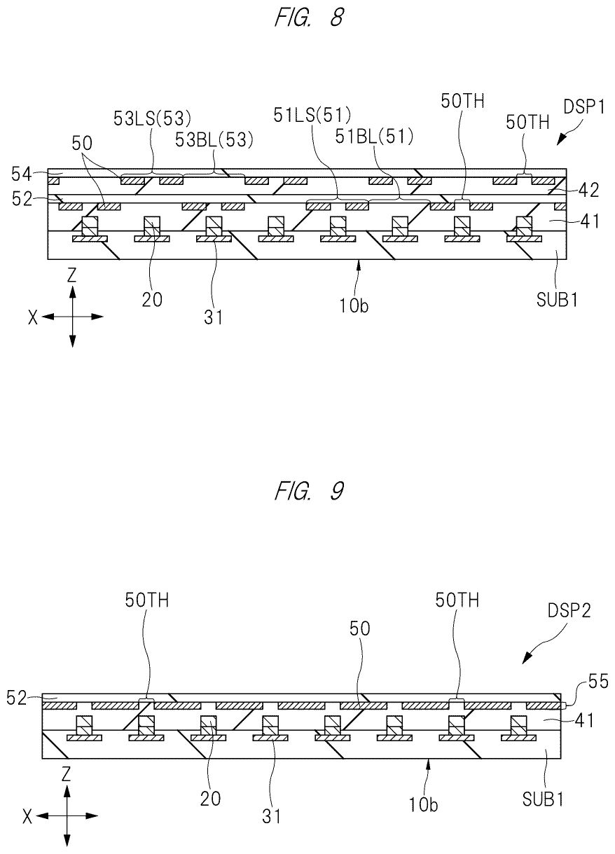

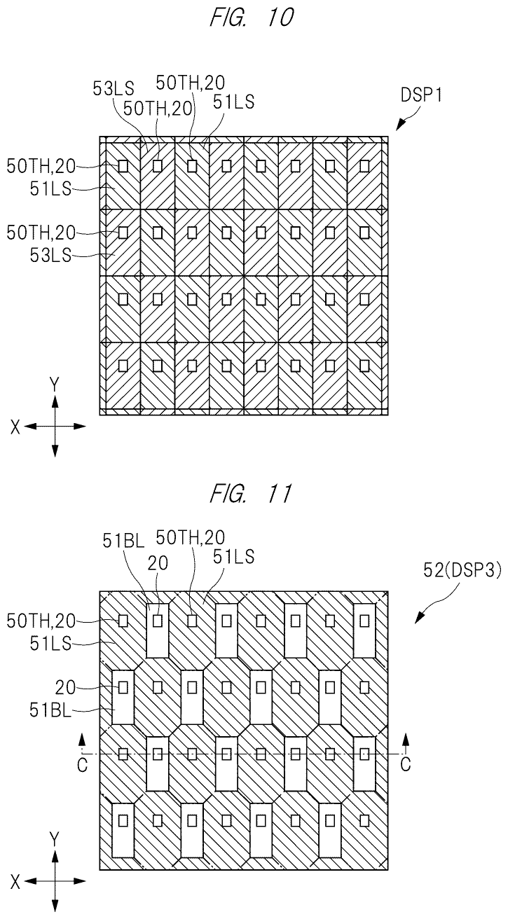

Next, the light shielding layer 51 and the light shielding layer 53 illustrated in FIG. 4 and FIG. 5 will be described in detail. FIG. 6 is an enlarged plan view illustrating a light shielding layer of two light shielding layers illustrated in FIG. 4 and FIG. 5, which is arranged at a position relatively closer to an LED element, and a substrate supporting it. FIG. 7 is an enlarged plan view illustrating a light shielding layer of the two light shielding layers illustrated in FIG. 4 and FIG. 5, which is arranged at a position relatively farther from the LED element, and a substrate supporting it. FIG. 8 is an enlarged cross-sectional view taken along the line C-C in FIG. 6 and FIG. 7. FIG. 9 is an enlarged cross-sectional view illustrating a studied example for FIG. 8. FIG. 10 is a transparent enlarged plan view illustrating a state where the substrate illustrated in FIG. 6 and the substrate illustrated in FIG. 7 are overlapped with each other. Each of FIG. 6, FIG. 7, and FIG. 10 is a plan view, but hatching is applied to the light shielding portions (light shielding members) so as to make the locations where the light shielding portions are arranged easy to see. Hereinafter, hatching is applied in the same manner for the plan views illustrating the positions of the light shielding portions.

The resin layer 41 illustrated in FIG. 8 is a spacer member for ensuring a separation distance between the light shielding layer 51 (more specifically, the substrate 52 supporting the light shielding layer 51) and the LED element 20. The resin layer 42 is a spacer member for ensuring a separation distance between the light shielding layer 53 (more specifically, the substrate 54 supporting the light shielding layer 53) and the light shielding layer 51 (more specifically, the substrate 52 supporting the light shielding layer 51).

In the case of the spacer members described above, it is preferable to use a material that is in liquid or paste form when formed and can be cured by applying energy after the formation. In particular, since it is preferable to seal the LED element 20 such that no air bubbles remain, it is preferable that the material constituting the resin layer 41 has a certain degree of fluidity when formed.

In the case of this embodiment, each of the resin layer 41 and the resin layer 42 is made of an organic material containing a photocurable resin component that is cured by light irradiation. An example of the photocurable resin is an ultraviolet-curable resin that is cured by irradiating ultraviolet light.

The light shielding layer 51 includes a plurality of light shielding portions 51LS and a plurality of openings 51BL that are alternately arranged along each of the X direction and the Y direction intersecting with the direction. The light × shielding layer 53 includes a plurality of light shielding portions 53LS and a plurality of openings 53BL that are alternately arranged along each of the X direction and the Y direction. The openings 51BL are through holes that penetrate the light shielding layer 51 illustrated in FIG. 8 in the thickness direction. The openings 53BL are through holes that penetrate the light shielding layer 53 illustrated in FIG. 8 in the thickness direction.

Each of the plurality of light shielding portions 51LS and the plurality of light shielding portions 53LS has an opening (through hole) 50TH arranged at a position that overlaps with any of the plurality of LED elements 20. The opening 50TH is a hole through which the light emitted from the LED element 20 passes. The opening 50TH is formed so as to penetrate the light shielding portion 51LS or the light shielding portion 53LS in the thickness direction (Z direction). The resin layer 41 or the resin layer 42 is buried in the opening 50TH.

Considering the emission efficiency of light from the opening 50TH, each of the plurality of openings 50TH is preferably arranged at a position that overlaps with the LED element 20.

Further, an opening area of the opening 50TH is smaller than an opening area of the opening 51BL and an opening area of the opening 53BL. Each of the plurality of light shielding portions 53LS is arranged at a position that overlaps with any of the plurality of openings 51BL. Each of the plurality of light shielding portions 51LS is arranged at a position that overlaps with any of the plurality of openings 53BL. In the case of this embodiment, the light shielding layer has a two-layer structure, and thus each of the plurality of openings 53BL is arranged at a position that overlaps with any of the plurality of light shielding portions 51LS. Also, each of the plurality of openings 51BL is arranged at a position that overlaps with any of the plurality of light shielding portions 53LS. In this way, it is possible to suppress the intrusion of external light and the emission of reflected light described above, and to visually recognize the light emitted from the LED element 20.

Incidentally, when paying attention to the effect of suppressing the intrusion of external light and the emission of reflected light, the same effect can be obtained even when a single light shielding layer is provided instead of providing a plurality of light shielding layers as in this embodiment. For example, a display device DSP2 illustrated in FIG. 9 includes a single light shielding layer 55 having a plurality of openings 50TH. The light shielding layer 55 does not have the opening 51BL provided in the light shielding layer 51 or the opening 53BL provided in the light shielding layer 53 illustrated in FIG. 8. In the display device DSP2, most of the external light entering from above the LED element 20 is absorbed (shielded) by the light shielding layer 55. Also, even when the external light enters through any of the plurality of openings 53BL and is reflected by the wiring pattern (for example, the wiring 31), most of the reflected light is absorbed (shielded) by the light shielding layer 55. Therefore, in the case of the display device DSP2 as well, it is possible to suppress the intrusion of external light and the emission of reflected light described above, and to visually recognize the light emitted from the LED element 20.

However, in the case of the display device DSP2, there are following problems. That is, since an occupied area of the light shielding member 50 is large in the light shielding layer 55, the light (for example, ultraviolet light) irradiated to cure the resin layer 41 does not easily reach the resin layer 41. Therefore, curing of the resin layer 41 is inhibited by the light shielding layer 55 particularly at the position that overlaps with the light shielding member 50.

As another method of curing the resin layer 41, it is conceivable to irradiate light (for example, ultraviolet light) from the side of the surface 10b. However, even in this case, the light irradiated from the side of the surface 10b is reflected by the plurality of wiring patterns formed on the substrate SUB1, making it difficult for the light to reach the resin layer 41.

From the above viewpoint, the inventors of this application have studied a structure that suppresses the intrusion of external light and the emission of reflected light described above and that makes it easy to irradiate the resin layer 41 with light for curing the resin layer 41, and have found the structure of this embodiment.

In the case of this embodiment, the light shielding layer 51 covering the resin layer 41 has the plurality of openings 51BL each having an area larger than that of the opening 50TH in addition to the plurality of openings 50TH. In the case of this embodiment, the planar shape of each of the light shielding portions 51LS and the openings 51BL is a quadrangle (for example, a rectangle). Also, in the case of this embodiment, the area of each of the plurality of light shielding portions 51LS and the area of each of the plurality of openings 51BL are equal to each other. Therefore, considering the area occupied by the openings 50TH, the occupied area ratio of the light shielding members 50 in the entire light shielding layer 51, in other words, the light shielding ratio of the light shielding layer 51, is less than 50%. Therefore, when comparing the display device DSP1 illustrated in FIG. 8 with the display device DSP2 illustrated in FIG. 9, the entire resin layer 41 is more easily irradiated with light (for example, ultraviolet light) for curing the resin layer 41 in the display device DSP1 than in the display device DSP2.

In FIG. 8, the light shielding layer 51 is covered with the light shielding layer 53. However, the process of irradiating the resin layer 41 with light for curing the resin layer 41 is performed before the resin layer 42 is stacked on the light shielding layer 51 (more specifically, on the substrate 52 supporting the light shielding layer 51). Therefore, the amount of light irradiated to the resin layer 41 in the process of curing the resin layer 41 is determined by the light shielding ratio (in other words, the aperture ratio) of the light shielding layer 51 regardless of the light shielding ratio (in other words, the aperture ratio) of the light shielding layer 53.

In addition, the display device DSP1 includes the resin layer 42 containing a photocurable resin component as described above. Therefore, it is necessary to irradiate the resin layer 42 with light (for example, ultraviolet light) to cure the resin layer 42 after arranging the light shielding layer 53 and the substrate 54 so as to cover the resin layer 42.

In the case of this embodiment, the light shielding layer 53 covering the resin layer 42 has the plurality of openings 53BL each having an area larger than that of the opening 50TH in addition to the plurality of openings 50TH. In the case of this embodiment, the planar shape of each of the light shielding portions 53LS and the openings 53BL is a quadrangle (for example, a rectangle). Also, in the case of this embodiment, the area of each of the plurality of light shielding portions 53LS and the area of each of the plurality of openings 53BL are equal to each other. Therefore, considering the area occupied by the openings 50TH, the occupied area ratio of the light shielding members 50 in the entire light shielding layer 53, in other words, the light shielding ratio of the light shielding layer 53, is less than 50%. In the case of the display device DSP1, in the process of curing the resin layer 42, the entire resin layer 42 is more easily irradiated with light (for example, ultraviolet light) for curing the resin layer 42 as in the process of irradiating the resin layer 41 with light.

As described above, according to this embodiment, each of the resin layer 41 and the resin layer 42 must be cured, but the structure capable of easily irradiating each of the resin layer 41 and the resin layer 42 with light is provided.

As described above, each of the plurality of light shielding portions 53LS is arranged at a position that overlaps with any of the plurality of openings 51BL, and each of the plurality of openings 53BL is arranged at a position that overlaps with any of the plurality of light shielding portions 51LS. Therefore, as illustrated in FIG. 10, in the state where the substrate 52 illustrated in FIG. 6 and the substrate 54 illustrated in FIG. 7 are overlapped, the substrate SUB1 (see FIG. 8) is covered with any of the plurality of light shielding portions 51LS and the plurality of light shielding portions 53LS in the part other than the plurality of openings 50TH in a transparent plan view. Therefore, as described above, the display device DSP1 can suppress the intrusion of external light and the emission of reflected light described above.

Furthermore, in the case of this embodiment, the plurality of light shielding portions and the plurality of openings are arranged so as to correspond one-to-one with of the plurality of LED elements. In more detail, as illustrated in FIG. 6, any one of the plurality of LED elements 20 is arranged at the position that overlaps with each of the plurality of light shielding portions 51LS and the plurality of openings 51BL. Furthermore, as illustrated in FIG. 7, another one of the plurality of LED elements 20 is arranged at the position that overlaps with each of the plurality of light shielding portions 53LS and the plurality of openings 53BL.

For example, since the plurality of light shielding portions 51LS and the plurality of openings 51BL illustrated in FIG. 6 are arranged at the position that overlaps with one of the plurality of LED elements, the area of each of the light shielding portions 51LS and the openings 51BL is small. Therefore, this is preferable in the point that the range of the region that the light for curing the resin layer 41 does not reach can be made small in the process of curing the resin layer 41 illustrated in FIG. 8.

Incidentally, in the case of the display device DSP1, the light shielding layer 51 is supported by the substrate 52 and the light shielding layer 53 is supported by the substrate 54. In other words, the light transmissive substrate 52 is interposed between the resin layer 41 and the resin layer 42, and the light shielding layer 51 is fixed to the substrate 52. Further, the light transmissive substrate 54 is provided on the resin layer 42, and the light shielding layer 53 is fixed to the substrate 54. For example, a glass substrate or a transparent resin substrate may be used as the light transmissive substrates 52 and 54.

As a modification for this embodiment, each of the light shielding layer 51 and the light shielding layer 53 may be provided without providing the substrate 52 or the substrate 54. As another modification, the structure in which either one of the substrate 52 and the substrate 54 is not provided is also possible.

In the case of the structure in which the substrate 52 is not provided, it is preferable that the plurality of light shielding portions 51LS in the light shielding layer 51 are connected to each other. When the plurality of light shielding portions 51LS are connected to each other, the light shielding layer 51 can be handled as one member. Also, in the case of the structure in which the substrate 54 is not provided, it is preferable that the plurality of light shielding portions 53LS in the light shielding layer 53 are connected to each other. When the plurality of light shielding portions 53LS are connected to each other, the light shielding layer 53 can be handled as one member.

On the other hand, in the case of the structure in which the light shielding layer 51 is fixed to the substrate 52 as in this embodiment, there is a high degree of freedom in terms of the shape and thickness of the light shielding layer 51. For example, in the case where the plurality of light shielding portions 51LS in the light shielding layer 51 are separated from each other and each of the plurality of light shielding portions 51LS is fixed to the substrate 52, the set of the light shielding layer 51 and the substrate 52 can be handled as one member. Further, for example, in the case where each of the plurality of light shielding portions 51LS is fixed to the substrate 52, the thickness of the light shielding portion 51LS can be made extremely thin within the range capable of acquiring the light shielding property. Similarly, in the case of the structure in which the light shielding layer 53 is fixed to the substrate 54, there is a high degree of freedom in terms of the shape and thickness of the light shielding layer 53.

### Modification of Shape of Light Shielding Portion

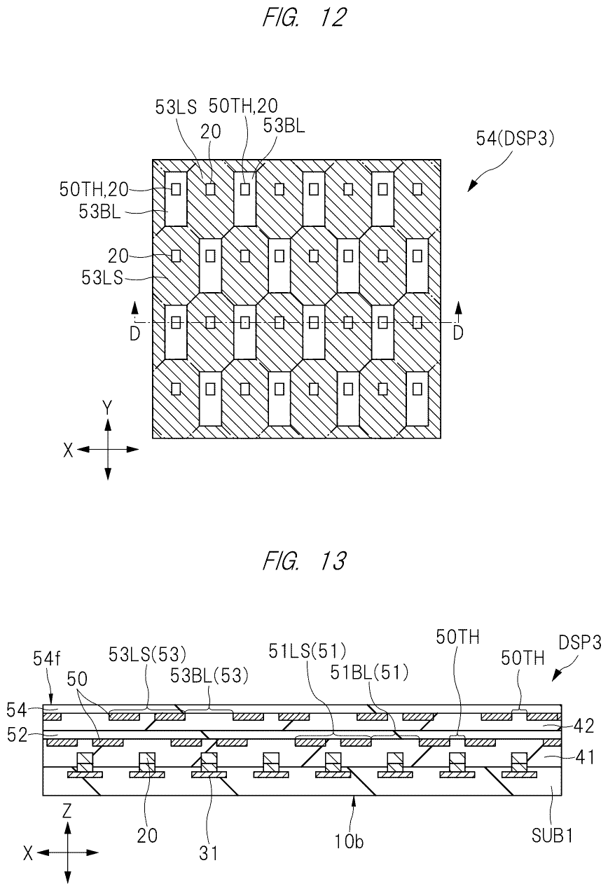

Next, a typical modification of the light shielding layer described above will be described. FIG. 11 is an enlarged plan view illustrating a modification of the light shielding layer illustrated in FIG. 6. FIG. 12 is an enlarged plan view illustrating a modification of the light shielding layer illustrated in FIG. 7. FIG. 13 is an enlarged cross-sectional view taken along the line D-D in FIG. 11 and FIG. 12. In FIG. 11, boundaries of the plurality of light shielding portions 51LS are indicated by two-dot dashed lines.

A display device DSP3 illustrated in FIG. 11 to FIG. 13 is different from the display device DSP1 illustrated in FIG. 6 to FIG. 8 in the following points. First, as illustrated in FIG. 11, the area of each of the plurality of light shielding portions 51LS in the light shielding layer 51 (see FIG. 13) of the display device DSP3 is larger than the opening area of each of the plurality of openings 51BL. Also, as illustrated in FIG. 12, the area of each of the plurality of light shielding portions 53LS in the light shielding layer 53 (see FIG. 13) of the display device DSP3 is larger than the opening area of each of the plurality of openings 53BL. In addition, as illustrated in FIG. 13, the peripheral edge portion of each of the plurality of light shielding portions 51LS overlaps with any of the plurality of light shielding portions 53LS.

In the example illustrated in FIG. 11 and FIG. 12, each of the plurality of light shielding portions 51LS and the plurality of light shielding portions 53LS is a hexagon. Each of the plurality of openings 51BL and the plurality of openings 51BL is a quadrangle having an area smaller than those of the plurality of openings 51BL and the plurality of openings 51BL illustrated in FIG. 6 and FIG. 7. The plurality of light shielding portions 51LS illustrated in FIG. 11 are connected to each other. The plurality of light shielding portions 53LS illustrated in FIG. 12 are connected to each other.

In the case of the display device DSP3, the opening area of each of the plurality of openings 51BL and the plurality of openings 51BL is smaller than that of the display device DSP1 illustrated in FIG. 6 to FIG. 8, and thus the total amount of light reaching the resin layer 41 and the resin layer 42 becomes smaller.

On the other hand, in the case of the structure in which the peripheral edge portion of each of the plurality of light shielding portions 51LS overlaps with any of the plurality of light shielding portions 53LS as illustrated in FIG. 13, it is possible to shield not only the external light entering from the normal direction of a surface 54f of the substrate 54 but also the external light entering from a direction inclined with respect to the normal direction. Therefore, the display device DSP3 is preferable from the viewpoint of suppressing the intrusion of external light and the emission of reflected light.

The display device DSP3 illustrated in FIG. 11 to FIG. 13 is similar to the display device DSP1 described with reference to FIG. 1 to FIG. 10 except for the differences described above. Therefore, duplicated descriptions will be omitted.

### Modification of Layer Structure of Light Shielding Layer

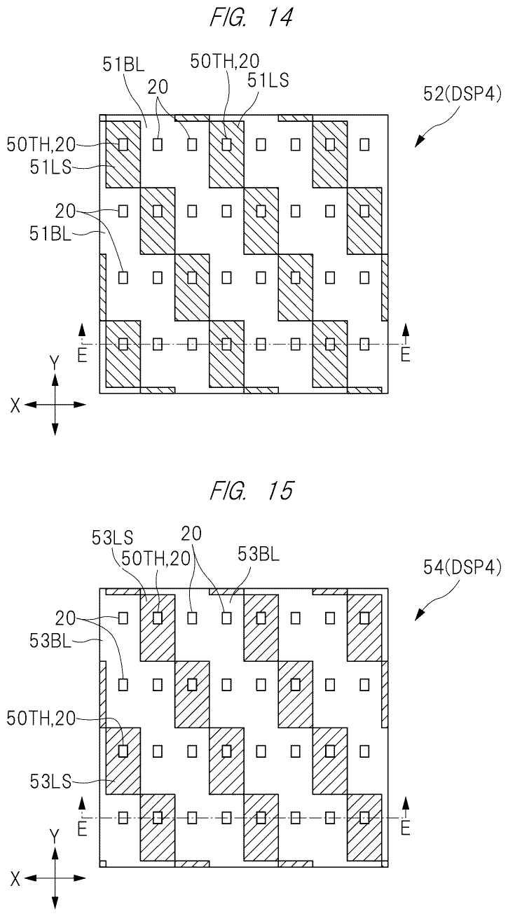

Each of the display device DSP1 and the display device DSP3 described above is a display device including a light shielding layer with a two-layer structure. However, the number of layers in the light shielding layer is not limited to two, and may be three or more. For example, a display device DSP4 illustrated in FIG. 14 to FIG. 17 is a modification including a light shielding layer with a three-layer structure.

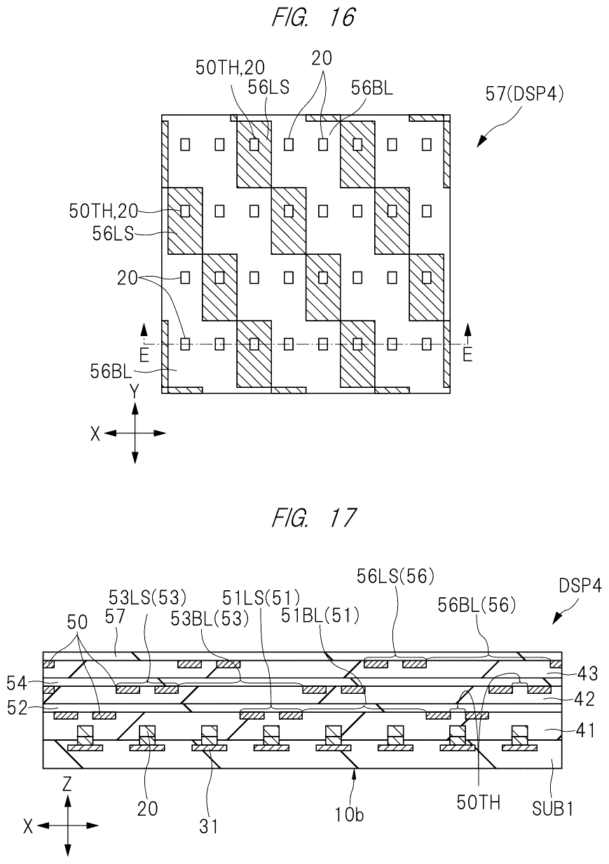

FIG. 14 is an enlarged plan view illustrating another modification of the light shielding layer illustrated in FIG. 6. FIG. 15 is an enlarged plan view illustrating another modification of the light shielding layer illustrated in FIG. 7. FIG. 16 is an enlarged plan view illustrating an example of a layout of a light shielding layer stacked on the substrate illustrated in FIG. 15. FIG. 17 is an enlarged cross-sectional view taken along the line E-E in FIG. 14, FIG. 15, and FIG. 16.

As illustrated in FIG. 17, the display device DSP4 includes the resin layer 41 that seals the LED elements 20, the light shielding layer 51 arranged on the resin layer 41, the resin layer 42 arranged on the light shielding layer 51 (more specifically, on the substrate 52 supporting the light shielding layer 51), the light shielding layer 53 arranged on the resin layer 42, a resin layer 43 arranged on the light shielding layer 53 (more specifically, on the substrate 54 supporting the light shielding layer 53), and a light shielding layer 56 arranged on the resin layer 43.

The light shielding layer 56 is supported by a substrate 57 like the light shielding layer 51 and the light shielding layer 53. The substrate 57 supporting the light shielding layer 56 is a light transmissive substrate (for example, a glass substrate or a transparent resin substrate) like the substrate 52 and the substrate 54.

Like the resin layer 41 and the resin layer 42, the resin layer 43 is made of an organic material containing a photocurable resin component that is cured by light irradiation (for example, ultraviolet light). Each of the resin layer 41, the resin layer 42, and the resin layer 43 is made of, for example, the same material.

The light shielding member 50 is partially arranged in each of the light shielding layer 51, the light shielding layer 53, and the light shielding layer 56.

As illustrated in FIG. 14, the light shielding layer 51 (see FIG. 17) includes the plurality of light shielding portions 51LS and the plurality of openings 51BL that are alternately arranged along each of the X direction and the Y direction intersecting with the X direction. In the X direction, each of the plurality of light shielding portions 51LS is arranged at a position that overlaps with one LED element 20, and each of the plurality of openings 51BL is arranged at a position that overlaps with two LED elements 20. Similarly, in the Y direction, each of the plurality of light shielding portions 51LS is arranged at a position that overlaps with one LED element 20, and each of the plurality of openings 51BL is arranged at a position that overlaps with two or more LED elements 20.

As illustrated in FIG. 15, the light shielding layer 53 (see FIG. 17) includes the plurality of light shielding portions 53LS and the plurality of openings 53BL that are alternately arranged along each of the X direction and the Y direction intersecting with the X direction. In the X direction, each of the plurality of light shielding portions 53LS is arranged at a position that overlaps with one LED element 20, and each of the plurality of openings 53BL is arranged at a position that overlaps with two LED elements 20. Similarly, in the Y direction, each of the plurality of light shielding portions 53LS is arranged at a position that overlaps with one LED element 20, and each of the plurality of openings 53BL is arranged at a position that overlaps with two or more LED elements 20.

As illustrated in FIG. 16, the light shielding layer 56 (see FIG. 17) includes a plurality of light shielding portions 56LS and a plurality of openings 56BL that are alternately arranged along each of the X direction and the Y direction intersecting with the X direction. In the X direction, each of the plurality of light shielding portions 56LS is arranged at a position that overlaps with one LED element 20, and each of the plurality of openings 56BL is arranged at a position that overlaps with two LED elements 20. Similarly, in the Y direction, each of the plurality of light shielding portions 56LS is arranged at a position that overlaps with one LED element 20, and each of the plurality of openings 56BL is arranged at a position that overlaps with two or more LED elements 20.

The plurality of light shielding portions 51LS (see FIG. 14), the plurality of light shielding portions 53LS (see FIG. 15), and the plurality of light shielding portions 56LS (see FIG. 16) each include the opening 50TH arranged at a position that overlaps with any of the plurality of LED elements 20. The opening area of the opening 50TH is smaller than the opening area of each of the opening 51BL (see FIG. 14), the opening 53BL (see FIG. 15), and the opening 56BL (see FIG. 16).

Each of the plurality of light shielding portions 51LS illustrated in FIG. 14 overlaps with any of the plurality of openings 53BL illustrated in FIG. 15, and overlaps with any of the plurality of openings 56BL illustrated in FIG. 16. Each of the plurality of light shielding portions 53LS illustrated in FIG. 15 overlaps with any of the plurality of openings 51BL illustrated in FIG. 14, and overlaps with any of the plurality of openings 56BL illustrated in FIG. 16. Each of the plurality of light shielding portions 56LS illustrated in FIG. 16 overlaps with any of the plurality of openings 51BL illustrated in FIG. 14, and overlaps with any of the plurality of openings 53BL illustrated in FIG. 15.

Further, each of the plurality of openings 51BL illustrated in FIG. 14 overlaps with any of the plurality of light shielding portions 53LS illustrated in FIG. 15 or any of the plurality of light shielding portions 56LS illustrated in FIG. 16. Each of the plurality of openings 53BL illustrated in FIG. 15 overlaps with any of the plurality of light shielding portions 51LS illustrated in FIG. 14 or any of the plurality of light shielding portions 56LS illustrated in FIG. 16. Each of the plurality of openings 56BL illustrated in FIG. 16 overlaps with any of the plurality of light shielding portions 51LS illustrated in FIG. 14 or any of the plurality of light shielding portions 53LS illustrated in FIG. 15.

In the case of this modification, the three-layer structure is adopted for the light shielding layer, and thus the light shielding ratio of each of the light shielding layer 51, the light shielding layer 53, and the light shielding layer 56 can be reduced (in other words, the aperture ratio thereof can be increased) as compared with the example described with reference to FIG. 6 to FIG. 8. Therefore, the amount of light irradiated to the resin layer can be increased in the process of curing each of the resin layer 41, the resin layer 42, and the resin layer 43 illustrated in FIG. 17 as compared with the example described with reference to FIG. 6 to FIG. 8.

Also, in the case where the light shielding layer 51, the light shielding layer 53, and the light shielding layer 56 are overlapped with each other, the substrate SUB1 illustrated in FIG. 17 is covered with any of the plurality of light shielding portions 51LS, the plurality of light shielding portions 53LS, and the plurality of light shielding portions 56LS in the part other than the plurality of openings 50TH in a transparent plan view, as in the display device DSP1 described with reference to FIG. 10. Therefore, in the case of the display device DSP4 as well, it is possible to suppress the intrusion of external light and the emission of reflected light described above as in the display device DSP1 described above.

Although an example of the three-layer structure has been described in this modification, the four or more layer structure may be adopted for the light shielding layer. However, when the number of layers for the light shielding layer increases, the process for curing the resin layers also increases. Therefore, efficiency, considering the manufacturing the two-layer structure illustrated in FIG. 6 to FIG. 8 or the three-layer structure illustrated in FIG. 14 to FIG. 17 is particularly preferable.

The display device DSP4 illustrated in FIG. 14 to FIG. 17 is similar to the display device DSP1 described with reference to FIG. 1 to FIG. 10 except for the differences described above. Therefore, duplicated descriptions will be omitted.

In the foregoing, the embodiment and typical modifications have been described, but the above-described technique can be applied to various modifications other than the modifications described above. For example, the above-described modifications can be used in combination.

A person having ordinary skill in the art can conceive of various alterations and corrections within a range of the idea of the present invention, and it is interpreted that the alterations and corrections also belong to the scope of the present invention. For example, the embodiment obtained by performing addition or elimination of components or design change or the embodiment obtained by performing addition or reduction of process or condition change to the embodiment described above by a person having an ordinary skill in the art is also included in the scope of the present invention as long as it includes the gist of the present invention.

The present invention can be applied to display devices and electronic devices incorporating display devices.

What is claimed is:

1. A display device comprising:
a plurality of light emitting diode elements mounted on a first substrate;
a first resin layer that seals the plurality of light emitting diode elements;
a first light shielding layer arranged on the first resin layer;
a second resin layer arranged on the first light shielding layer; and
a second light shielding layer arranged on the second resin layer,
wherein each of the first resin layer and the second resin layer is made of an organic material containing a photocurable resin component that is cured by light irradiation,
wherein the first light shielding layer includes a plurality of first light shielding portions and a plurality of first openings that are alternately arranged along each of a first direction and a second direction intersecting with the first direction,
wherein the second light shielding layer includes a plurality of second light shielding portions and a plurality of second openings that are alternately arranged along each of the first direction and the second direction,
wherein each of the plurality of first light shielding portions and the plurality of second light shielding portions includes a third opening arranged at a position that overlaps with any of the plurality of light emitting diode elements,
wherein an opening area of the third opening is smaller than an opening area of the first opening and an opening area of the second opening,
wherein each of the plurality of first light shielding portions is arranged at a position that overlaps with any of the plurality of second openings, and
wherein each of the plurality of second light shielding portions is arranged at a position that overlaps with any of the plurality of first openings.

2. The display device according to claim 1,
wherein a light transmissive second substrate is interposed between the first resin layer and the second resin layer, and the first light shielding layer is fixed to the second substrate.

3. The display device according to claim 2,
wherein a light transmissive third substrate is provided on the second resin layer, and
wherein the second light shielding layer is fixed to the third substrate.

4. The display device according to claim 1,
wherein each of the plurality of first openings is arranged at a position that overlaps with any of the plurality of second light shielding portions, and
wherein each of the plurality of second openings is arranged at a position that overlaps with any of the plurality of first light shielding portions.

5. The display device according to claim 4,
wherein an opening shape of each of the plurality of first light shielding portions, the plurality of second light shielding portions, the plurality of first openings, and the plurality of second openings is a quadrangle.

6. The display device according to claim 4,
wherein an area of each of the plurality of first light shielding portions and the opening area of each of the plurality of first openings are equal to each other, and
wherein an area of each of the plurality of second light shielding portions and the opening area of each of the plurality of second openings are equal to each other.

7. The display device according to claim 4,
wherein an area of each of the plurality of first light shielding portions is larger than the opening area of each of the plurality of first openings,
wherein an area of each of the plurality of second light shielding portions is larger than the opening area of each of the plurality of second openings, and
wherein a peripheral edge portion of each of the plurality of first light shielding portions overlaps with any of the plurality of second light shielding portions.

8. The display device according to claim 1,
wherein a wiring pattern connected to any of the plurality of light emitting diode elements is formed between the first substrate and the plurality of light emitting diode elements.

9. The display device according to claim 1,
wherein any one of the plurality of light emitting diode elements is arranged at a position that overlaps with each of the plurality of first light shielding portions and the plurality of first openings, and
wherein another one of the plurality of light emitting diode elements is arranged at a position that overlaps with each of the plurality of second light shielding portions and the plurality of second openings.
